(19) United States
(12) Patent Application Publication
(10) Pub. No.: US 2024/0421095 A1
(43) Pub. Date: Dec. 19, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chih-Hung Cheng, Hsinchu (TW); Pei-Ching Kuo, Hsinchu City (TW); Yi-Hsiu Chen, Hsinchu City (TW)

(73) Assignee: Taiwan Semiconductor Manufacturing Company, Ltd., Hsinchu (TW)

(21) Appl. No.: 18/337,040

(22) Filed: Jun. 19, 2023

(51) Int. Cl. H01L 23/538; H01L 21/48; H01L 23/00; H01L 23/528; H01L 25/00; H01L 25/18; H10B 80/00

(52) U.S. Cl. CPC H01L 23/5386; H01L 21/486; H01L 23/528; H01L 24/02; H01L 24/05; H01L 24/80; H01L 25/18; H01L 25/50; H10B 80/00; H01L 23/481; H01L 23/49827; H01L 24/32; H01L 2224/02372; H01L 2224/02381; H01L 2224/0239; H01L 2224/024; H01L 2224/0401; H01L 2224/05569; H01L 2224/0557; H01L 2224/05624; H01L 2224/05647; H01L 2224/05655; H01L 2224/05666; H01L 2224/05684; H01L 2224/08145; H01L 2224/32225; H01L 2224/32245; H01L 2224/8001; H01L 2224/80895; H01L 2224/80896; H01L 2924/01013; H01L 2924/01022; H01L 2924/01028; H01L 2924/01029; H01L 2924/01074; H01L 2924/0635; H01L 2924/066; H01L 2924/0665; H01L 2924/067; H01L 2924/07025

(57) ABSTRACT

A semiconductor device includes a bridge carrier, a first die, a second die, a first encapsulant, a cap carrier, a third die, and a second encapsulant. The bridge carrier includes a carrier substrate and a bridge redistribution structure disposed on the carrier substrate. The first die and the second die are disposed side by side on the bridge carrier. The bridge redistribution structure electrically connects the first die and the second die. The first encapsulant laterally encapsulates the first die and the second die. The cap carrier is disposed over the first die and the second die. The third die is located between the first die and the cap carrier. The second encapsulant laterally encapsulates the third die.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more of the smaller components to be integrated into a given area. These smaller electronic components also require smaller packages that utilize less area than previous packages. Some smaller types of packages for semiconductor components include quad flat packages (QFP), pin grid array (PGA) packages, ball grid array (BGA) packages, flip chips (FC), three-dimensional integrated circuits (3DICs), wafer level packages (WLPs), package-on-package (POP) structures, and integrated fan-out (InFO) packages, etc. Although existing semiconductor devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1L are schematic cross-sectional views illustrating a manufacturing process of a semiconductor device in accordance with some embodiments of the disclosure.

FIG. 2 is a schematic top view of FIG. 1F.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

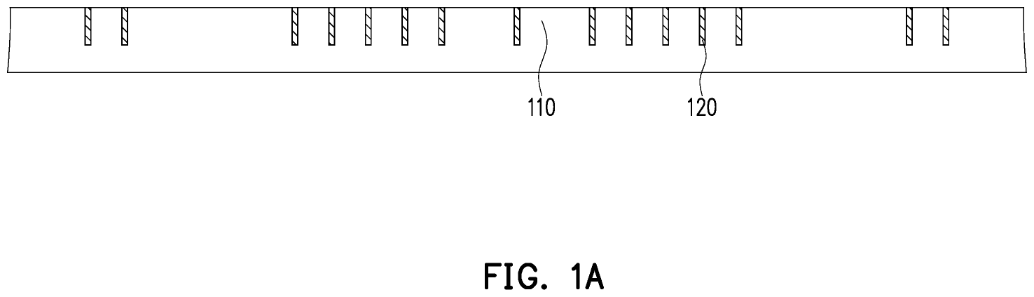

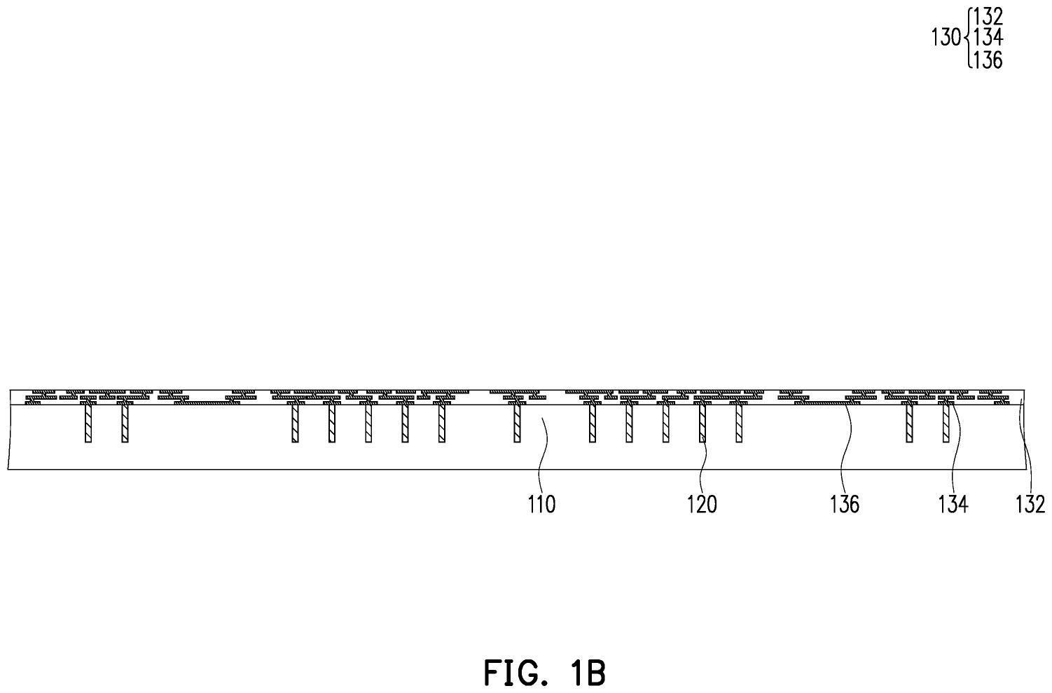

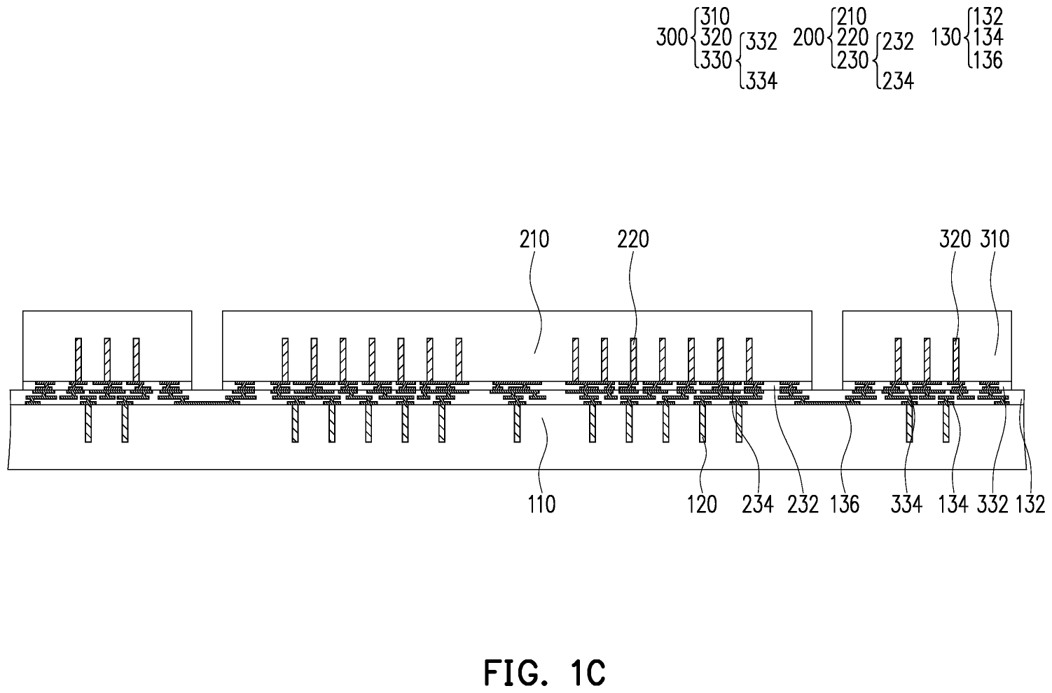

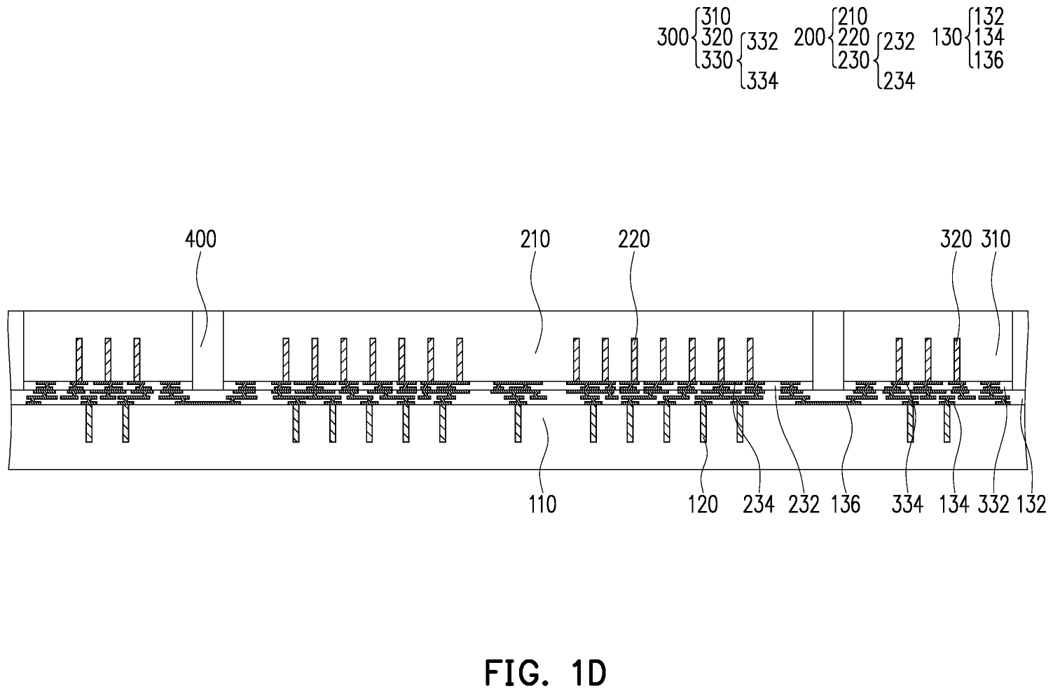

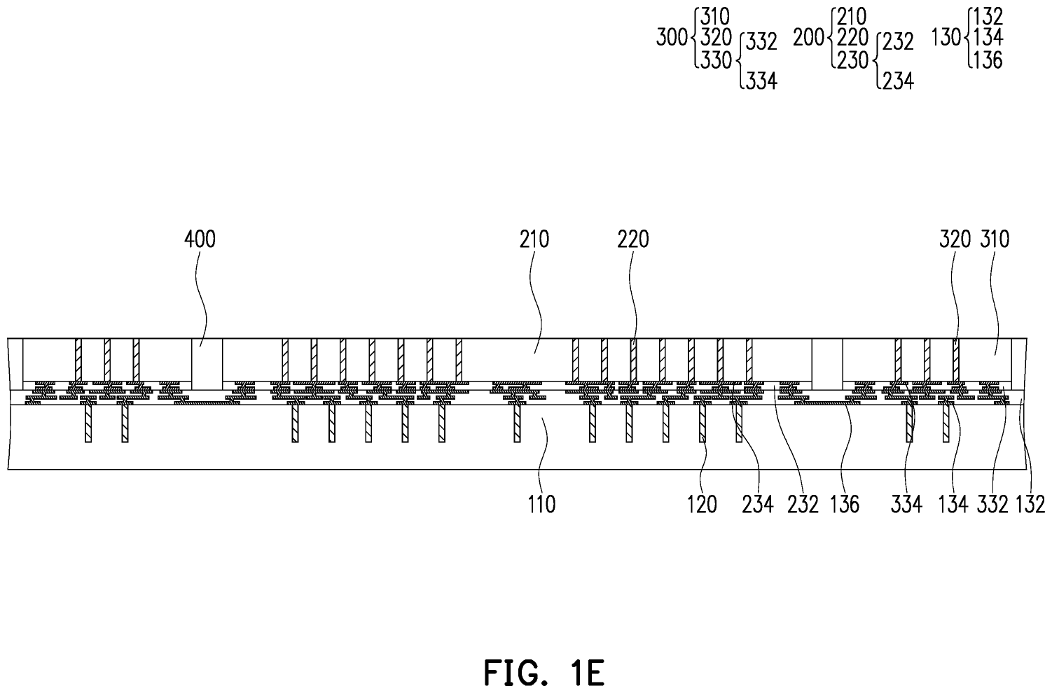

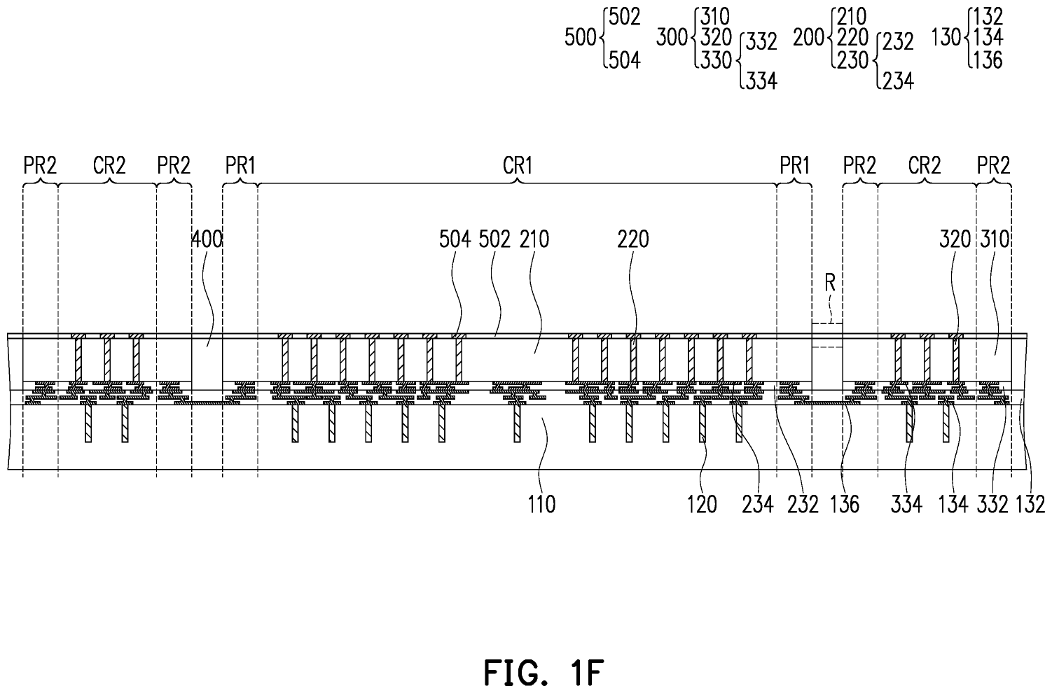

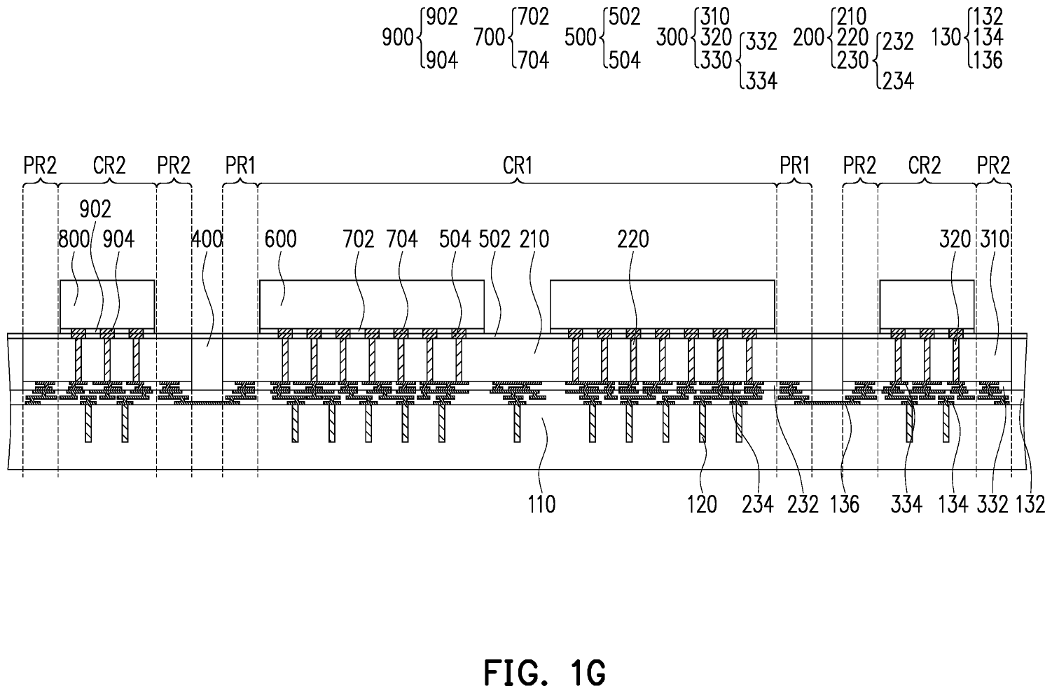

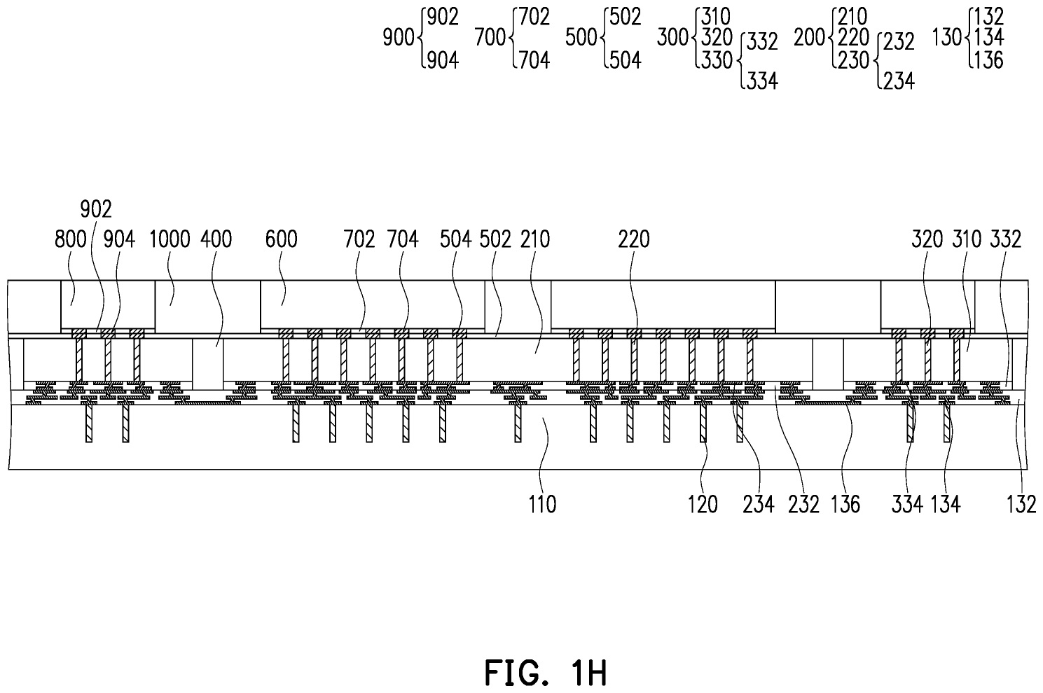

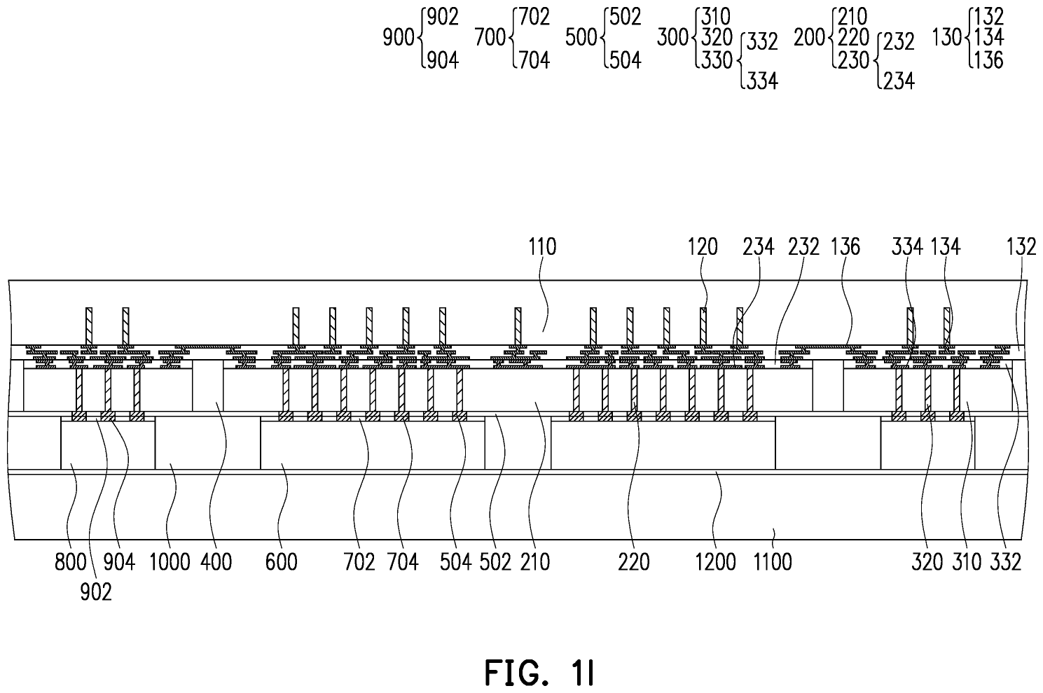

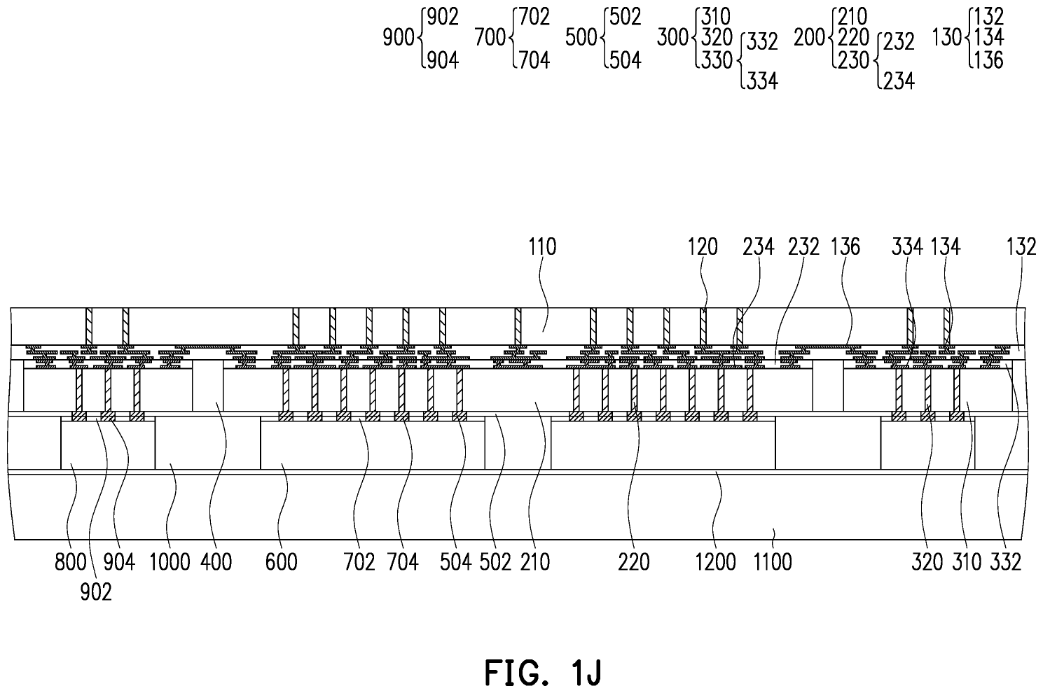

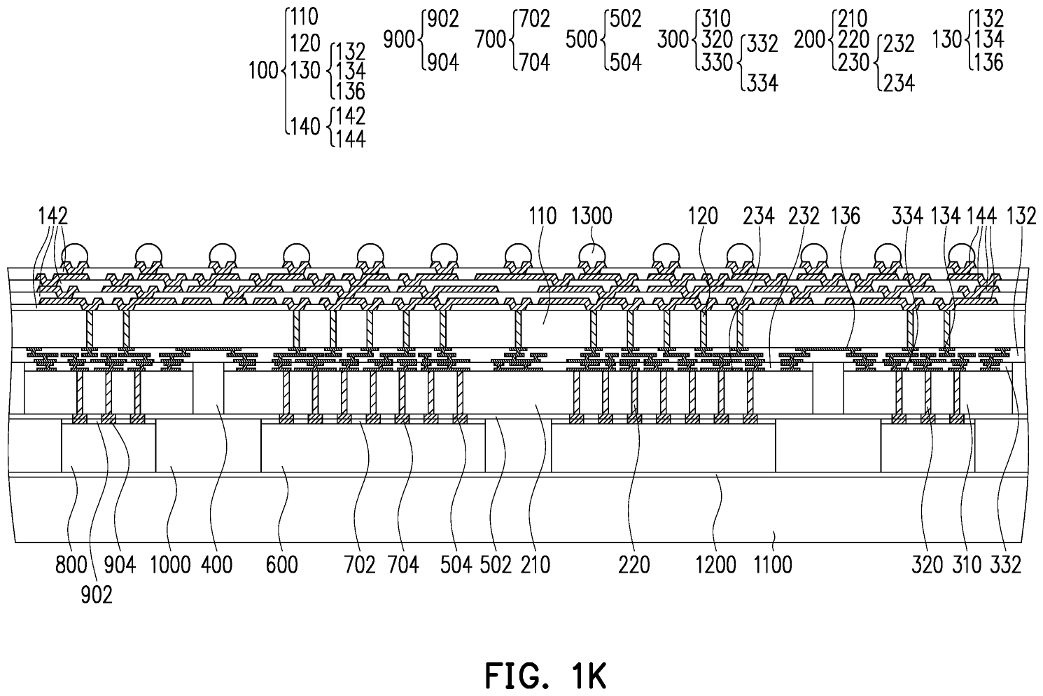

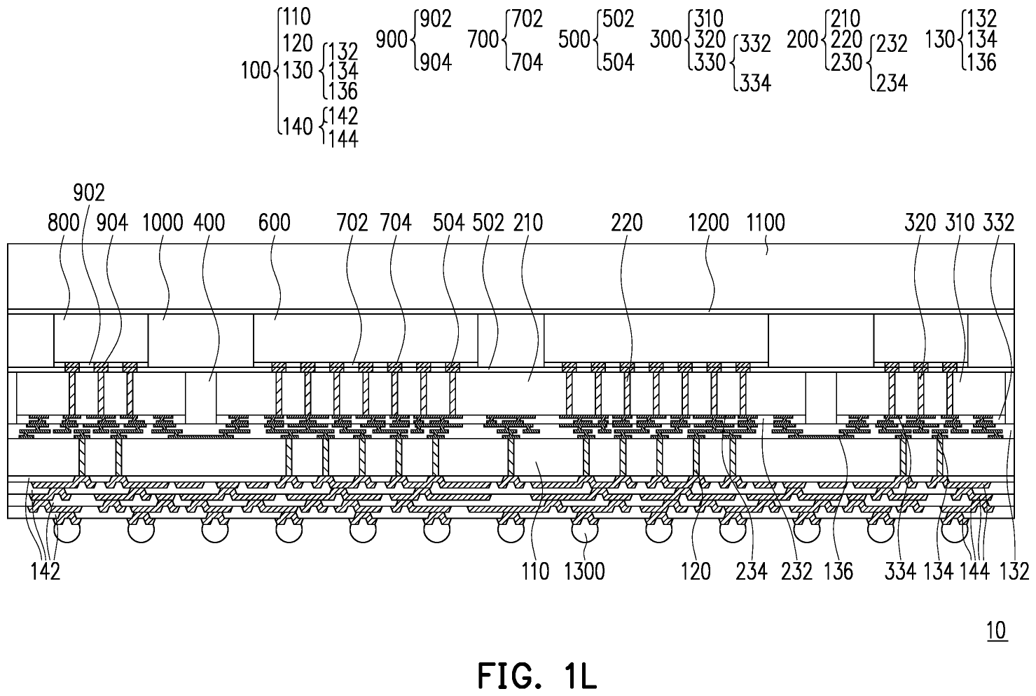

FIG. 1A to FIG. 1L are schematic cross-sectional views illustrating a manufacturing process of a semiconductor device 10 in accordance with some embodiments of the disclosure. Referring to FIG. 1A, a carrier substrate 110 is provided. In some embodiments, the carrier substrate 110 is made of a semiconducting material. For example, the carrier substrate 110 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. However, the disclosure is not limited thereto. In some alternative embodiments, the carrier substrate 110 is made of an insulating material. For example, the carrier substrate 110 is made of glass, ceramics, or the like. In some embodiments, the carrier substrate 110 includes active components (e.g., transistors or the like) and/or passive components (e.g., resistors, capacitors, inductors, or the like) formed therein. However, the disclosure is not limited thereto. In some alternative embodiments, the carrier substrate 110 may be a dummy substrate that is free of active component and passive component.

In some embodiments, a plurality of through vias 120 is formed in the carrier substrate 110. As illustrated in FIG. 1A, the through vias 120 are embedded in the carrier substrate 110. For example, one end of each through via 120 is coplanar with a top surface of the carrier substrate 110 while another end of each through via 120 is covered by the carrier substrate 110. In other words, one end of each through via 120 is exposed by the carrier substrate 110 while another end of each through via 120 is not revealed. In some embodiments, a material of the through vias 120 includes aluminum, titanium, copper, nickel, tungsten, or alloys thereof. In some embodiments, the through vias 120 are in physical contact with the carrier substrate 110. However, the disclosure is not limited thereto. In some alternative embodiments, a barrier layer (not shown) is sandwiched between the through vias 120 and the carrier substrate 110. In some embodiments, materials of the barrier layer include titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), or a combination thereof. In some embodiments, the barrier layer is also referred to as a “liner layer.”

Referring to FIG. 1B, a bridge redistribution structure 130 is formed on the carrier substrate 110 and the through vias 120. In some embodiments, the bridge redistribution structure 130 includes a dielectric layer 132, a plurality of routing patterns 134, and a plurality of bridge patterns 136. In some embodiments, a material of the dielectric layer 132 includes polyimide, epoxy resin, acrylic resin, phenol resin, benzocyclobutene (BCB), polybenzooxazole (PBO), or any other suitable polymer-based dielectric material. Alternatively, the dielectric layer 132 may be formed of oxides or nitrides, such as silicon oxide, silicon nitride, aluminum oxide, hafnium oxide, hafnium zirconium oxide, or the like. In some embodiments, the dielectric layer 132 includes resin mixed with filler. The dielectric layer 132 may be formed by suitable fabrication techniques, such as spin-on coating, chemical vapor deposition (CVD), plasma-enhanced chemical vapor deposition (PECVD), or the like. For simplicity, the dielectric layer 132 is illustrated as a bulky layer in FIG. 1B, but it should be understood that the dielectric layer 132 may be constituted by multiple dielectric layers.

In some embodiments, the routing patterns 134 and the bridge patterns 136 are embedded in the dielectric layer 132. In some embodiments, the routing patterns 134 located at different level heights (i.e. different tiers) are connected to one another through the conductive vias therebetween. Similarly, the bridge patterns 136 located at different level heights (i.e. different tiers) are connected to one another through the conductive vias therebetween. As illustrated in FIG. 1B, corresponding tiers of the routing patterns 134 and the bridge patterns 136 are located at the same level height. That is, corresponding tiers of the routing patterns 134 and the bridge patterns 136 are formed simultaneously through the same process. In some embodiments, a material of the routing patterns 134 and the bridge patterns 136 includes aluminum, titanium, copper, nickel, tungsten, or alloys thereof. The routing patterns 134 and the bridge patterns 136 may be formed by electroplating, deposition, and/or photolithography and etching.

In some embodiments, the routing patterns 134 are electrically connected to the through vias 120. For example, the bottommost tier of the routing patterns 134 is in physical contact with the through via 120 to render electrical connection with the through vias 120. On the other hand, the bridge patterns 136 are spatially separated from the through vias 120. Nevertheless, the bridge patterns 136 may be electrically connected to the through vias 120 through the routing patterns 134 horizontally. As illustrated in FIG. 1B, the topmost tier of the routing patterns 134 and the topmost tier of the bridge patterns 136 are exposed by the dielectric layer 132. It should be noted that the number of the routing patterns 134 and the number of the bridge patterns 136 illustrated in FIG. 1B are merely for illustrative purposes, and the disclosure is not limited thereto. In some alternative embodiments, fewer or more layers of the routing patterns 134 and the bridge patterns 136 may be formed depending on the circuit design.

Referring to FIG. 1C, a first die 200 and a plurality of second dies 300 are bonded to the bridge redistribution structure 130. In some embodiments, the first die 200 includes a semiconductor substrate 210, a plurality of through semiconductor vias (TSV) 220, and an interconnection structure 230. In some embodiments, the semiconductor substrate 210 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor substrate 210 includes active components (e.g., transistors or the like) and/or passive components (e.g., resistors, capacitors, inductors, or the like) formed therein.

In some embodiments, the TSVs 220 are embedded in the semiconductor substrate 210. For example, one end of each TSV 220 is coplanar with a bottom surface of the semiconductor substrate 210 while another end of each TSV 220 is covered by the semiconductor substrate 210. In some embodiments, a material of the TSVs 220 includes aluminum, titanium, copper, nickel, tungsten, or alloys thereof. In some embodiments, the TSVs 220 are in physical contact with the semiconductor substrate 210. However, the disclosure is not limited thereto. In some embodiments, a barrier layer (not shown) is sandwiched between the TSVs 220 and the semiconductor substrate 210. In some embodiments, materials of the barrier layer include TIN, TaN, TiSiN, TaSiN, WSiN, TiC, TaC, TiAlC, TaAlC, TiAlN, TaAlN, or a combination thereof. In some embodiments, the barrier layer is also referred to as a “liner layer.”

In some embodiments, the interconnection structure 230 is formed on the semiconductor substrate 210 and the TSVs 220. In some embodiments, the interconnection structure 230 includes a dielectric layer 232 and a plurality of routing patterns 234. In some embodiments, a material of the dielectric layer 232 includes polyimide, epoxy resin, acrylic resin, phenol resin, BCB, PBO, or any other suitable polymer-based dielectric material. Alternatively, the dielectric layer 232 may be formed of oxides or nitrides, such as silicon oxide, silicon nitride, aluminum oxide, hafnium oxide, hafnium zirconium oxide, or the like. In some embodiments, the dielectric layer 232 includes resin mixed with filler. The dielectric layer 232 may be formed by suitable fabrication techniques, such as spin-on coating. CVD, PECVD, or the like. For simplicity, the dielectric layer 232 is illustrated as a bulky layer in FIG. 1C, but it should be understood that the dielectric layer 232 may be constituted by multiple dielectric layers.

In some embodiments, the routing patterns 234 are embedded in the dielectric layer 232. In some embodiments, the routing patterns 234 located at different level heights (i.e. different tiers) are connected to one another through the conductive vias therebetween. In some embodiments, a material of the routing patterns 234 includes aluminum, titanium, copper, nickel, tungsten, or alloys thereof. The routing patterns 234 may be formed by electroplating, deposition, and/or photolithography and etching. In some embodiments, the routing patterns 234 are electrically connected to the TSVs 220. For example, some of the routing patterns 234 in the topmost tier thereof are in physical contact with the TSVs 220 to render electrical connection with the TSVs 220. As illustrated in FIG. 1C, the bottommost tier of the routing patterns 234 are exposed by the dielectric layer 232. It should be noted that the number of the routing patterns 234 illustrated in FIG. 1C is merely for illustrative purposes, and the disclosure is not limited thereto. In some alternative embodiments, fewer or more layers of the routing patterns 234 may be formed depending on the circuit design.

In some embodiments, the first die 200 is capable of performing logic functions. For example, the first die 200 may be a Central Process Unit (CPU) die, a Graphic Process Unit (GPU) die, a Field-Programmable Gate Array (FPGA), or the like. However, the disclosure is not limited thereto. In some alternative embodiments, the first die 200 is capable of performing storage functions. For example, the first die 200 may be a Dynamic Random Access Memory (DRAM), a Resistive Random Access Memory (RRAM), or a Static Random Access Memory (SRAM). Examples of the DRAM include High Bandwidth Memory (HBM), Wide I/O (WIO) Memory, Low-Power Double Date Rate (LPDDR) DRAM, or the like.

In some embodiments, each second die 300 includes a semiconductor substrate 310, a plurality of TSVs 320, and an interconnection structure 330. In some embodiments, the interconnection structure 330 includes a dielectric layer 332 and a plurality of routing patterns 334. The semiconductor substrate 310, the TSVs 320, the dielectric layer 332, and the routing patterns 334 of the second die 300 are respectively similar to the semiconductor substrate 210, the TSVs 220, the dielectric layer 232, and the routing patterns 234 of the first die 200, so the detailed descriptions thereof are omitted herein.

In some embodiments, each of the second die 300 is capable of performing logic functions. For example, each of the second die 300 may be a CPU die, a GPU die, a FPGA, or the like. However, the disclosure is not limited thereto. In some alternative embodiments, each of the second die 300 is capable of performing storage functions. For example, each of the second die 300 may be a DRAM, a RRAM, or a SRAM. Examples of the DRAM include HBM, WIO Memory, LPDDR DRAM, or the like.

As illustrated in FIG. 1C, the first die 200 and the second dies 300 are disposed side by side on the bridge redistribution structure 130. In some embodiments, the first die 200 and the second dies 300 are picked-and-placed onto the bridge redistribution structure 130 and are bonded to the bridge redistribution structure 130 through a hybrid bonding process.

The hybrid bonding process of the first die 200 and the bridge redistribution structure 130 will be described in detail below. In some embodiments, to facilitate the hybrid bonding between the first die 200 and the bridge redistribution structure 130, surface preparation for bonding surfaces of the first die 200 and the bridge redistribution structure 130 may be performed. The surface preparation may include surface cleaning and activation, for example. Surface cleaning may be performed to remove particles on the bonding surfaces of the first die 200 and the bridge redistribution structure 130. In some embodiments, these bonding surfaces may be cleaned by wet cleaning, for example. Not only particles are removed, but also native oxide formed on these bonding surfaces may be removed. Thereafter, activation of these bonding surfaces may be performed for development of high bonding strength. In some embodiments, plasma activation may be performed to treat the bonding surfaces. When the activated top surface of the dielectric layer 132 is in contact with the activated bottom surface of the dielectric layer 232, the dielectric layer 132 of the bridge redistribution structure 130 and the dielectric layer 232 of the first die 200 are pre-bonded.

After pre-bonding the first die 200 onto the bridge redistribution structure 130, hybrid bonding of the first die 200 and the bridge redistribution structure 130 is performed. The hybrid bonding of the first die 200 and the bridge redistribution structure 130 may include a thermal treatment for dielectric bonding and a thermal annealing for conductor bonding. In some embodiments, the thermal treatment for dielectric bonding is performed to strengthen the bonding between the dielectric layers 132, 232. For example, the thermal treatment for dielectric bonding may be performed at temperature ranging from about 100 Celsius degree to about 150 Celsius degree. After performing the thermal treatment for dielectric bonding, the thermal annealing for conductor bonding is performed to facilitate the bonding between the routing patterns 134, the bridge patterns 136, and the routing patterns 234. For example, the thermal annealing for conductor bonding may be performed at temperature ranging from about 300 Celsius degree to about 400 Celsius degree. The process temperature of the thermal annealing for conductor bonding is higher than that of the thermal treatment for dielectric bonding. After performing the thermal annealing for conductor bonding, the dielectric layer 232 is bonded to the dielectric layer 132 and the routing patterns 234 are bonded to the routing patterns 134 and the bridge patterns 136.

In some embodiments, the second dies 300 are also hybrid bonded to the bridge redistribution structure 130. For example, the second dies 300 may be bonded to the bridge redistribution structure 130 through similar manner as that of the first die 200 and the bridge redistribution structure 130, so the detailed description thereof is omitted herein. As illustrated in FIG. 1C, the dielectric layer 332 is hybrid bonded to the dielectric layer 132 and the routing patterns 334 are hybrid bonded to the routing patterns 134 and the bridge patterns 136.

As illustrated in FIG. 1C, the interconnection structure 230 of the first die 200 and the interconnection structures 330 of the second dies 300 are in physical contact with the bridge redistribution structure 130. In some embodiments, the bridge patterns 136 extend from the first die 200 to the second dies 300 to electrically connect the first die 200 and the second dies 300. That is, the bridge redistribution structure 130 electrically connects the first die 200 and the second dies 300.

Referring to FIG. 1D, a first encapsulant 400 is formed on the bridge redistribution structure 130 to laterally encapsulate the first die 200 and the second dies 300. For example, the first encapsulant 400 is formed to fill in the gaps between the first die 200 and the second dies 300. In some embodiments, the first encapsulant 400 is in physical contact with the bridge redistribution structure 130. In some embodiments, the first encapsulant 400 includes a molding compound, a molding underfill, a resin (such as epoxy), or the like. In some alternative embodiments, the first encapsulant 400 may include silicon oxide and/or silicon nitride. In some embodiments, the first encapsulant 400 is formed through CVD, PECVD, atomic layer deposition (ALD), or the like. In some embodiments, the first encapsulant 400 is free of filler. In some embodiments, the first encapsulant 400 is referred to as “gap fill oxide.”

As illustrated in FIG. 1D, the bottommost tier of the bridge patterns 136 extends directly underneath the first encapsulant 400 to electrically connect the first die 200 and the second dies 300. That is, the first encapsulant 400 is vertically overlapped with some of the bridge patterns 136. For example, a vertical projection of at least a portion of the bridge patterns 136 onto the carrier substrate 110 is overlapped with a vertical projection of the first encapsulant 400 onto the carrier substrate 110.

Referring to FIG. 1D and FIG. 1E, a planarization process is performed on the first die 200, the second dies 300, and the first encapsulant 400. In some embodiments, the planarization process includes a mechanical grinding process and/or a chemical mechanical polishing (CMP) process. In some embodiments, the semiconductor substrate 210 of the first die 200, the semiconductor substrates 310 of the second dies 300, and the first encapsulant 400 are grinded until the TSVs 220 of the first die 200 and the TSVs 320 of the second dies 300 are both revealed. For example, after the planarization process, the TSVs 220 penetrate through the semiconductor substrate 210 and the TSVs 320 penetrate through the semiconductor substrates 310. In some embodiments, the TSVs 220 allow electrical communication between the front side and the back side of the first die 200. Meanwhile, the TSVs 320 allow electrical communication between the front side and the back side of each second die 300. In some embodiments, after the TSVs 220 and the TSVs 320 are revealed, the first die 200, the second dies 300, and the first encapsulant 400 are further grinded to reduce the overall thicknesses of the first die 300 and the second dies 300. In some embodiments, after the TSVs 220 and the TSVs 320 are revealed, the semiconductor substrate 210 and the semiconductor substrates 310 are recessed such that each TSV 220 protrudes from the semiconductor substrate 210 and each TSV 320 protrudes from the semiconductor substrates 310. Thereafter, a dielectric layer (not shown) may fill into the recess to laterally wrap around the protruded portion of each TSV 220 and each TSV 320. In some embodiments, the dielectric layer that fills into the recess includes low temperature silicon nitride or the like. However, the disclosure is not limited thereto. In some alternative embodiments, the foregoing recessing step may be omitted.

Referring to FIG. 1F, a bonding layer 500 is conformally formed on the first die 200, the second dies 300, and the first encapsulant 400. In some embodiments, the bonding layer 500 includes a bonding dielectric layer 502 and a plurality of bonding pads 504. In some embodiments, the bonding pads 504 are embedded in the bonding dielectric layer 502. For example, the bonding pads 504 are laterally encapsulated by the bonding dielectric layer 502. In some embodiments, each bonding pad 504 is revealed by the bonding dielectric layer 502 at both top and bottom surfaces of the bonding dielectric layer 502. In some embodiments, the bonding pads 504 are electrically connected to the TSVs 220 of the first die 200 and the TSVs 320 of the second dies 300. For example, the bonding pads 504 are in physical contact with TSVs 220 of the first die 200 and the TSVs 320 of the second dies 300. In some embodiments, a material of the bonding dielectric layer 502 includes silicon oxide, silicon nitride, silicon oxynitirde, or other suitable dielectric materials. On the other hand, a material of the bonding pads 504 includes copper or other suitable metallic materials.

In some embodiments, the bonding dielectric layer 502 is formed by first depositing a dielectric material layer (not shown) on the first die 200, the second dies 300, and the first encapsulant 400. Thereafter, the dielectric material layer is patterned to form the bonding dielectric layer 502 having a plurality of openings. In some embodiments, locations of these openings correspond to the TSVs 220 and the TSVs 320. In other words, these openings expose each TSV 220 and each TSV 320. Then, a conductive material layer is deposited on the bonding dielectric layer 502 and the TSVs 220, 320 exposed by the openings of the bonding dielectric layer 502. Subsequently, a polishing process (e.g., a chemical mechanical polishing process) is performed to partially remove the conductive material layer until the top surface of the bonding dielectric layer 502 is exposed. After performing the polishing process, the bonding pads 504 are formed in the openings of the bonding dielectric layer 502.

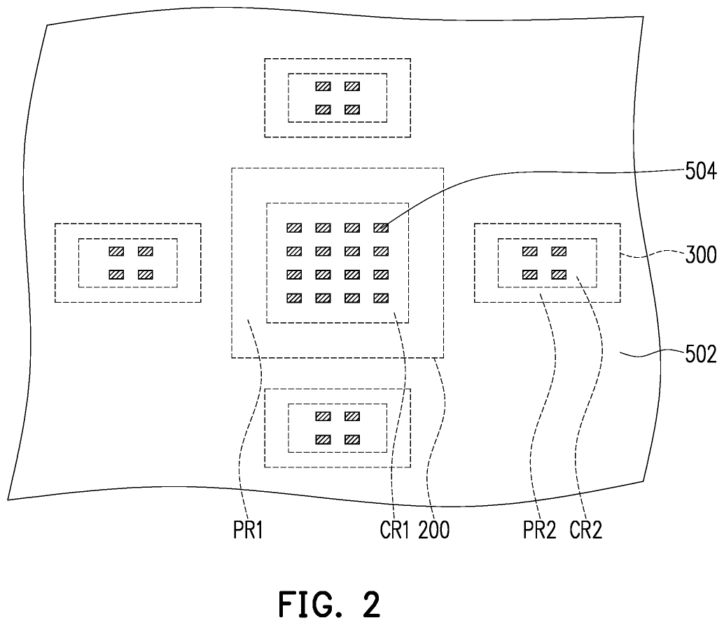

The arrangement of the bonding pads 504 relative to the first die 200 and the second dies 300 will be described below in conjunction with FIG. 1F and FIG. 2. FIG. 2 is a schematic top view of FIG. 1F. Referring to FIG. 1F and FIG. 2, the first die 200 has a central region CR1 and a peripheral region PR1 surrounding the central region CR1. Similarly, each second die 300 has a central region CR2 and a peripheral region PR2 surrounding the central region CR2. In some embodiments, the bonding pads 504 are concentrated in the central region CR1 of the first die 200 and the central regions CR2 of the second dies 300. For example, the bonding pads 504 are completely located in the central region CR1 of the first die 200 and the central regions CR2 of the second dies 300. Meanwhile, the bonding pads 504 are not located in the peripheral region PR1 of the first die 200 and the peripheral regions PR2 of the second dies 300. That is, the peripheral region PR1 of the first die 200 and the peripheral regions PR2 of the second dies 300 are free of the bonding pads 504. Since the bonding pads 504 are completely located in the central region CR1 of the first die 200 and the central regions CR2 of the second dies 300, the first encapsulant 400 does not vertically overlap with any of the bonding pads 504. For example, as illustrated in FIG. 1F, a region R directly above the first encapsulant 400 is free of the bonding pads 504. That is, the region R directly above the first encapsulant 400 is completely occupied by the bonding dielectric layer 502.

As illustrated in FIG. 1F, the bridge patterns 136 of the bridge redistribution structure 130 are located in the peripheral region PR1 of the first die 200 and the peripheral regions PR2 of the second dies 300. Meanwhile, the bridge patterns 136 are not located in the central region CR1 of the first die 200 and the central regions CR2 of the second dies 300. In other words, the central region CR1 of the first die 200 and the central regions CR2 of the second dies 300 are free of the bridge patterns 136.

Referring to FIG. 1G, a plurality of third dies 600 is bonded to the first die 200 while a plurality of fourth dies 800 is bonded to the second dies 300. In some embodiments, each of the third dies 600 and each of the fourth dies 800 include active components (e.g., transistors or the like) and/or passive components (e.g., resistors, capacitors, inductors, or the like) formed therein. For example, the third dies 600 and the fourth dies 800 may be CPU dies, GPU dies, FPGA, DRAM, RRAM, SRAM, or the like. However, the disclosure is not limited thereto. In some alternative embodiments, each of the third dies 600 and each of the fourth dies 800 may be a dummy die that is free of active component and passive component. For example, the third dies 600 and the fourth dies 600 may not contribute to the operation of the subsequently formed semiconductor device 10.

In some embodiments, the third dies 600 are picked-and-placed onto the first die 200 and the fourth dies 800 are picked-and-placed onto the second dies 300. In some embodiments, prior to the placement of the third dies 600 and the fourth dies 800, a bonding layer 700 is formed on each of the third dies 600 and a bonding layer 900 is formed on each of the fourth dies 800. The bonding layer 700 includes a bonding dielectric layer 702 and a plurality of bonding pads 704. Similarly, the bonding layer 900 includes a bonding dielectric layer 902 and a plurality of bonding pads 904. In some embodiments, the bonding dielectric layers 702, 902 and the bonding pads 704, 904 are respectively similar to the bonding dielectric layer 502 and the bonding pads 504, so the detailed descriptions thereof are omitted herein.

In some embodiments, the third dies 300 are bonded to the first die 200 through a hybrid bonding process. For example, the third dies 300 are bonded to the first die 200 through the bonding layers 500 and 700. As illustrated in FIG. 1G, a top surface of the bonding dielectric layer 502 and top surfaces of the bonding pads 504 are substantially located at the same level height to provide an appropriate bonding surface for hybrid bonding. Similarly, a bottom surface of the bonding dielectric layer 702 and bottom surfaces of the bonding pads 704 are substantially located at the same level height to provide an appropriate bonding surface for hybrid bonding. In some embodiments, the third dies 600 are placed such that the bonding surfaces of the bonding layers 700 are in contact with the bonding surface of the bonding layer 500. For example, the third dies 600 are placed such that the bonding pads 504 are substantially aligned and in direct contact with the bonding pads 704.

In some embodiments, to facilitate the hybrid bonding between the bonding layer 500 and the bonding layers 700, surface preparation for bonding surfaces of the bonding layer 500 and the bonding layers 700 may be performed. The surface preparation may include surface cleaning and activation, for example. Surface cleaning may be performed on these bonding surfaces to remove particles on top/bottom surfaces of the bonding pads 504, 704 and the bonding dielectric layers 502, 702. In some embodiments, the bonding surfaces may be cleaned by wet cleaning, for example. Not only particles are removed, but also native oxide formed on the top/bottom surfaces of the bonding pads 504, 704 may be removed. The native oxide formed on the top/bottom surfaces of the bonding pads 504, 704 may be removed by chemicals used in wet cleaning processes, for example.

After cleaning the bonding surfaces of the bonding layer 500 and the bonding layers 700, activation of the top/bottom surfaces of the bonding dielectric layers 502, 702 may be performed for development of high bonding strength. In some embodiments, plasma activation may be performed to treat the top/bottom surfaces of the bonding dielectric layers 502, 702. When the activated top surface of the bonding dielectric layer 502 is in contact with the activated bottom surfaces of the bonding dielectric layers 702, the bonding dielectric layer 502 of the bonding layer 500 and the bonding dielectric layers 702 of the bonding layers 700 are pre-bonded.

After pre-bonding the bonding layers 700 onto the bonding layer 500, hybrid bonding of the third dies 600 and the first die 200 is performed. The hybrid bonding of the third dies 600 and the first die 200 may include a thermal treatment for dielectric bonding and a thermal annealing for conductor bonding. In some embodiments, the thermal treatment for dielectric bonding is performed to strengthen the bonding between the bonding dielectric layers 502, 702. For example, the thermal treatment for dielectric bonding may be performed at temperature ranging from about 100 Celsius degree to about 150 Celsius degree. After performing the thermal treatment for dielectric bonding, the thermal annealing for conductor bonding is performed to facilitate the bonding between the bonding pads 504, 704. For example, the thermal annealing for conductor bonding may be performed at temperature ranging from about 300 Celsius degree to about 400 Celsius degree. The process temperature of the thermal annealing for conductor bonding is higher than that of the thermal treatment for dielectric bonding. After performing the thermal annealing for conductor bonding, the bonding dielectric layers 702 are bonded to the bonding dielectric layer 502 and the bonding pads 704 are bonded to the bonding pads 504. In some embodiments, sidewalls of the bonding pads 504 are aligned with sidewalls of the bonding pads 704.

In some embodiments, the fourth dies 800 are also bonded to the second dies 300 through a hybrid bonding process. For example, the fourth dies 800 are bonded to the second dies 300 through the bonding layers 500 and 900. In some embodiments, the fourth dies 800 may be bonded to the second dies 300 through similar manner as that of the third dies 600 and the first die 200, so the detailed description thereof is omitted herein. As illustrated in FIG. 1G, the bonding dielectric layers 902 are hybrid bonded to the bonding dielectric layer 502 and the bonding pads 904 are hybrid bonded to the bonding pads 504. In some embodiments, sidewalls of the bonding pads 904 are aligned with sidewalls of the bonding pads 504.

As illustrated in FIG. 1G, the third dies 600 are completely located within a span of the first die 200 and the fourth dies 800 are completely located within a span of the second dies 300. For example, the third dies 600 are located in the central region CR1 of the first die 200 and are not located in the peripheral region PR1 of the first die 200. Similarly, the fourth dies 800 are located in the central regions CR2 of the second dies 300 and are not located in the peripheral regions PR2 of the second dies 300. As illustrated in FIG. 1G, the region directly above the first encapsulant 400 is die-free. That is, no die is disposed in the region directly above the first encapsulant 400.

Referring to FIG. 1H, a second encapsulant 1000 is formed on the bonding layer 500 to laterally encapsulate the third dies 600 and the fourth dies 800. For example, the bonding layer 500 is located between the first die 200 and the third dies 600, between the first die 200 and the second encapsulant 1000, and between the first encapsulant 400 and the second encapsulant 1000. In some embodiments, the second encapsulant 1000 is formed to fill in the gaps between the third dies 600 and the fourth dies 800. In some embodiments, the second encapsulant 1000 includes a molding compound, a molding underfill, a resin (such as epoxy), or the like. In some alternative embodiments, the second encapsulant 1000 may include silicon oxide and/or silicon nitride. In some embodiments, the second encapsulant 1000 is formed through CVD, PECVD, ALD, or the like. In some embodiments, the second encapsulant 1000 is free of filler. In some embodiments, the second encapsulant 1000 is referred to as “gap fill oxide.”

Referring to FIG. 1H and FIG. 1I, the structure illustrated in FIG. 1H is flipped upside down and is attached to a cap carrier 1100. For example, the third dies 600, the fourth dies 800, and the second encapsulant 1000 are attached to the cap carrier 1100 through a bonding film 1200. As illustrated in FIG. 1I, the cap carrier 1100 is disposed over the first die 200 and the second dies 300 such that the third dies 600 are located between the first die 200 and the cap carrier 1100 and the fourth dies 800 are located between the second dies 300 and the cap carrier 1100.

In some embodiments, the cap carrier 1100 is made of a semiconducting material. For example, the cap carrier 1100 is made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. However, the disclosure is not limited thereto. In some alternative embodiments, the cap carrier 1100 is made of an insulating material. For example, the cap carrier 1100 is made of glass, ceramics, or the like. In some embodiments, the cap carrier 1100 is a dummy carrier having no active component (e.g., transistors or the like), no passive component (e.g., resistors, capacitors, inductors, or the like), and no routing patterns formed therein. Under this scenario, the cap carrier 1100 merely provides mechanical strength for the subsequently formed semiconductor device 10 and does not contribute to the operation of the subsequently formed semiconductor device 10. However, the disclosure is not limited thereto. In some alternative embodiments, active component (e.g., transistors or the like), passive component (e.g., resistors, capacitors, inductors, or the like), and/or routing patterns may be formed in the cap carrier 1100 to contribute to the operation of the subsequently formed semiconductor device 10. For example, when routing patterns are presented in the cap carrier 1100, the routing patterns may serve as bridge patterns to electrically connect the third dies 600 and the fourth dies 800.

In some embodiments, the third dies 600, the fourth dies 800, and the second encapsulant 1000 are bonded to the cap carrier 1100 through fusion bonding. For example, a bonding film 1200 may be utilized to bond the third dies 600, the fourth dies 800, and the second encapsulant 1000 onto the cap carrier 1100. In some embodiments, the bonding film 1200 includes a die attach film (DAF) or other materials having adhesion property.

Referring to FIG. 1I and FIG. 1J, a planarization process is performed on the carrier substrate 110. In some embodiments, the planarization process includes a mechanical grinding process and/or a CMP process. In some embodiments, the carrier substrate 110 is grinded until the TSVs 120 are revealed. For example, after the planarization process, the TSVs 120 penetrate through at least a portion of the carrier substrate 110. In some embodiments, the TSVs 120 allow electrical communication between the front side and the back side of the carrier substrate 110. In some embodiments, after the TSVs 120 are revealed, the carrier substrate 110 is further grinded to reduce the overall thickness of the carrier substrate 110. In some embodiments, after the TSVs 120 are revealed, the carrier substrate 110 is recessed such that each TSV 120 protrudes from the carrier substrate 110. Thereafter, a dielectric layer (not shown) may fill into the recess to laterally wrap around the protruded portion of each TSV 120. In some embodiments, the dielectric layer that fills into the recess includes low temperature silicon nitride or the like. However, the disclosure is not limited thereto. In some alternative embodiments, the foregoing recessing step may be omitted.

Referring to FIG. 1K, a signal outputting redistribution structure 140 is formed on the carrier substrate 110 and the TSVs 120. In some embodiments, the signal outputting redistribution structure 140 includes a plurality of dielectric layers 142 and a plurality of conductive pattern layers 144. In some embodiments, the dielectric layers 142 and the conductive pattern layers 144 are stacked alternately. In some embodiments, the conductive pattern layers 144 are interconnected with one another through the conductive vias therebetween. For example, the conductive vias penetrate through the dielectric layers 142 to connect the conductive pattern layers 144. In some embodiments, each conductive pattern layer 144 includes a plurality of conductive patterns serving as redistribution wirings. In some embodiments, the conductive patterns of the topmost conductive pattern layer 144 shown in FIG. 1K may be referred to as under-ball metallurgy (UBM) patterns for ball mount.

In some embodiments, a material of the dielectric layers 142 includes polyimide, epoxy resin, acrylic resin, phenolic resin, BCB, PBO, or any other suitable polymer-based dielectric material. In some embodiments, the dielectric layers 142 include resin mixed with filler. The dielectric layers 142 may be formed by suitable fabrication techniques, such as film lamination, spin-on coating, CVD, PECVD, or the like. In some embodiments, a material of the conductive pattern layers 144 includes aluminum, titanium, copper, nickel, tungsten, or alloys thereof. The conductive pattern layers 144 may be formed by electroplating, deposition, and/or photolithography and etching. As illustrated in FIG. 1K, the conductive patterns of the bottommost conductive pattern layer 144 are in physical contact with the through vias 120. It should be noted that the number of the dielectric layers 142 and the number of the conductive pattern layers 144 illustrated in FIG. 1K are merely for illustrative purposes, and the disclosure is not limited thereto. In some alternative embodiments, fewer or more layers of the dielectric layers 142 and the conductive pattern layers 144 may be formed depending on the circuit design.

In some embodiments, the carrier substrate 110, the through vias 120, the bridge redistribution structure 130, and the signal outputting redistribution structure 140 are collectively referred to as a bridge carrier 100. As illustrated in FIG. 1K, the bridge redistribution structure 130 and the signal outputting redistribution structure 140 are disposed on two opposite sides of the carrier substrate 110. For example, the bridge redistribution structure 130 is disposed on one side of the carrier substrate 110 while the signal outputting redistribution structure 140 is disposed on another side of the carrier substrate 110. In other words, the bridge carrier 100 is a carrier having dual-side RDL (redistribution structure). In some embodiments, the through vias 120 penetrate through the carrier substrate 110 to electrically connect the bridge redistribution structure 130 and the signal outputting redistribution structure 140. As illustrated in FIG. 1K, the interconnection structure 230 of the first die 200 and the interconnection structures 330 of the second dies 300 are in physical contact with the bridge carrier 100. Similarly, the first encapsulant 400 is also in physical contact with the bridge carrier 100.

After the signal outputting redistribution structure 140 is formed on the carrier substrate 110 and the TSVs 120, a plurality of conductive terminals 1300 is formed on the signal outputting redistribution structure 140. For example, the conductive terminals 1300 are formed on the conductive patterns of the topmost conductive pattern layer 144. In some embodiments, the conductive terminals 1300 include solder balls, ball grid array (BGA) balls, or the like. In some embodiments, the conductive terminals 1300 are made of a conductive material with low resistivity, such as Sn, Pb, Ag, Cu, Ni, Bi, or an alloy thereof.

Referring to FIG. 1K and FIG. 1L, a singulation process is performed on the structure illustrated in FIG. 1K. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the structure shown in FIG. 1K to form trenches (not shown) in the said structure. Thereafter, a mechanical cutting process may be performed on the locations of the trenches to cut through the said structure, so as to obtain the semiconductor device 10 shown in FIG. 1L.

As illustrated in FIG. 1L, the bridge patterns 136 of the bridge redistribution structure 130 extend from the first die 200 to the second dies 300 to electrically connect the first die 200 and the second dies 300. That is, the bridge carrier 100 electrically connects the first die 200 and the second dies 300. With this configuration, the bridge die placed adjacent to the third dies 600 and the fourth dies 800 in the conventional structure may be omitted. As such, extra time and cost required for placing the bridge die and the short circuit issue derived from misalignment of the bridge die may be sufficient eliminated. Therefore, the fabrication cost of the semiconductor device 10 may be sufficient reduced while the yield of the semiconductor device 10 may be sufficiently increased.

In accordance with some embodiments of the disclosure, a semiconductor device includes a bridge carrier, a first die, a second die, a first encapsulant, a cap carrier, a third die, and a second encapsulant. The bridge carrier includes a carrier substrate and a bridge redistribution structure disposed on the carrier substrate. The first die and the second die are disposed side by side on the bridge carrier. The bridge redistribution structure electrically connects the first die and the second die. The first encapsulant laterally encapsulates the first die and the second die. The cap carrier is disposed over the first die and the second die. The third die is located between the first die and the cap carrier. The second encapsulant laterally encapsulates the third die.

In accordance with some alternative embodiments of the disclosure, a semiconductor device includes a bridge carrier, a first die, a second die, a first encapsulant, a bonding layer, and a third die. The first die and the second die are disposed side by side on the bridge carrier. The bridge carrier electrically connects the first die and the second die. The first die has a central region and a peripheral region surrounding the central region. The first encapsulant laterally encapsulates the first die and the second die. The bonding layer is disposed on the first die, the second die, and the first encapsulant. The bonding layer includes a bonding dielectric layer and bonding pads embedded in the bonding dielectric layer. The bonding pads are located in the central region of the first die. The third die is bonded to the first die through the bonding pads.

In accordance with some embodiments of the disclosure, a manufacturing method of a semiconductor device includes at least the following steps. A bridge carrier is formed by providing a carrier substrate and by forming a bridge redistribution structure on the carrier substrate. A first die and a second die are placed side by side on the bridge carrier so that the bridge redistribution structure electrically connects the first die and the second die. The first die and the second die are laterally encapsulated by a first encapsulant. A third die is bonded to the first die. The third die is laterally encapsulated by a second encapsulant. A cap carrier is attached to the third die and the second encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a bridge carrier, comprising:
a carrier substrate; and
a bridge redistribution structure disposed on the carrier substrate;
a first die and a second die disposed side by side on the bridge carrier, wherein the bridge redistribution structure electrically connects the first die and the second die;
a first encapsulant laterally encapsulating the first die and the second die;
a cap carrier disposed over the first die and the second die;
a third die located between the first die and the cap carrier; and
a second encapsulant laterally encapsulating the third die.

2. The semiconductor device of claim 1, wherein the bridge carrier further comprises:
a signal outputting redistribution structure disposed on the carrier substrate opposite to the bridge redistribution structure; and
through vias penetrating through at least a portion of the carrier substrate to electrically connect the bridge redistribution structure and the signal outputting redistribution structure.

3. The semiconductor device of claim 1, wherein the bridge redistribution structure comprises:
a dielectric layer;
routing patterns embedded in the dielectric layer;
bridge patterns embedded in the dielectric layer, wherein the bridge patterns extend from the first die to the second die to electrically connect the first die and the second die.

4. The semiconductor device of claim 3, wherein a vertical projection of at least a portion of the bridge patterns onto the carrier substrate is overlapped with a vertical projection of the first encapsulant onto the carrier substrate.

5. The semiconductor device of claim 1, further comprising a bonding layer located between the first die and the third die, between the first die and the second encapsulant, and between the first encapsulant and the second encapsulant, wherein the bonding layer comprises a bonding dielectric layer and bonding pads embedded in the bonding dielectric layer, and a region directly above the first encapsulant is free of the bonding pads.

6. The semiconductor device of claim 1, further comprising a fourth die located between the second die and the cap carrier, wherein the third die is completely located within a span of the first die, and the fourth die is completely located within a span of the second die.

7. The semiconductor device of claim 1, wherein the first die and the second die respectively comprise an interconnection structure, and the interconnection structure of the first die and the interconnection structure of the second die are in physical contact with the bridge redistribution structure.

8. The semiconductor device of claim 1, wherein the first encapsulant is in physical contact with the bridge redistribution structure.

9. A semiconductor device, comprising:
a bridge carrier;
a first die and a second die disposed side by side on the bridge carrier, wherein the bridge carrier electrically connects the first die and the second die, and the first die has a central region and a peripheral region surrounding the central region;
a first encapsulant laterally encapsulating the first die and the second die;
a bonding layer disposed on the first die, the second die, and the first encapsulant, wherein the bonding layer comprises a bonding dielectric layer and bonding pads embedded in the bonding dielectric layer, and the bonding pads are located in the central region of the first die; and
a third die bonded to the first die through the bonding layer.

10. The semiconductor device of claim 9, wherein the peripheral region of the first die is free of the bonding pads.

11. The semiconductor device of claim 9, wherein the bridge carrier comprises:
a carrier substrate;
a bridge redistribution structure disposed on one side of the carrier substrate and comprising:
a dielectric layer;
routing patterns embedded in the dielectric layer; and
bridge patterns embedded in the dielectric layer, wherein the bridge patterns are located in the peripheral region of the first die;
a signal outputting redistribution structure disposed on another side of the carrier substrate; and
through vias penetrating through at least a portion of the carrier substrate to electrically connect the bridge redistribution structure and the signal outputting redistribution structure.

12. The semiconductor device of claim 11, wherein a vertical projection of at least a portion of the bridge patterns onto the carrier substrate is overlapped with a vertical projection of the first encapsulant onto the carrier substrate.

13. The semiconductor device of claim 9, wherein the third die is located in the central region.

14. The semiconductor device of claim 9, further comprising:
a fourth die bonded to the second die through the bonding pads;
a second encapsulant laterally encapsulating the third die and the fourth die; and
a cap carrier attached to the third die, the fourth die, and the second encapsulant.

15. The semiconductor device of claim 9, wherein the first die and the second die respectively comprise an interconnection structure, and the interconnection structure of the first die and the interconnection structure of the second die are in physical contact with the bridge carrier.

16. The semiconductor device of claim 9, wherein the first encapsulant is in physical contact with the bridge carrier.

17. A manufacturing method of a semiconductor device, comprising:
forming a bridge carrier, comprising:
providing a carrier substrate;
forming a bridge redistribution structure on the carrier substrate;
placing a first die and a second die side by side on the bridge carrier so that the bridge redistribution structure electrically connects the first die and the second die;
laterally encapsulating the first die and the second die by a first encapsulant;
bonding a third die to the first die;
laterally encapsulating the third die by a second encapsulant; and
attaching a cap carrier to the third die and the second encapsulant.

18. The method of claim 17, wherein the bridge redistribution structure comprises bridge patterns, and the bridge patterns extend from the first die to the second die to electrically connect the first die and the second die.

19. The method of claim 18, wherein a vertical projection of at least a portion of the bridge patterns onto the carrier substrate is overlapped with a vertical projection of the first encapsulant onto the carrier substrate.

20. The method of claim 17, further comprising:
forming a bonding layer between the first die and the third die, between the first die and the second encapsulant, and between the first encapsulant and the second encapsulant, wherein the bonding layer comprises a bonding dielectric layer and bonding pads embedded in the bonding dielectric layer, and a region directly above the first encapsulant is free of the bonding pads.
